(19) United States
(12) Patent Application Publication
(10) Pub. No.: US 2024/0062840 A1
(43) Pub. Date: Feb. 22, 2024

(54) READ VERIFICATION CADENCE AND TIMING IN MEMORY DEVICES

(71) Applicant: MICRON TECHNOLOGY, INC., Boise, ID (US)

(72) Inventors: Michael Winterfeld, Firestone, CO (US); Byron D. Harris, Mead, CO (US); Tom Geukens, Longmont, CO (US); Juane Li, Milpitas, CA (US); Fangfang Zhu, San Jose, CA (US)

(21) Appl. No.: 17/889,214

(22) Filed: Aug. 16, 2022

(51) Int. Cl. G11C 16/34; G11C 11/56; G11C 16/10

(52) U.S. Cl. CPC G11C 16/3459; G11C 11/5628; G11C 11/5671; G11C 16/10

(57) ABSTRACT

A processing device in a memory sub-system performs a first pass of a multi-pass programming operation to coarsely program a first wordline, performs a second pass to coarsely program a second wordline adjacent to the first wordline, performs a third pass of a multi-pass programming operation to finely program the first wordline, performs a fourth pass of a multi-pass programming operation to coarsely program a third wordline adjacent to the second wordline, performs a fifth pass of a multi-pass programming operation to finely program the second wordline, and responsive to determining that at least the second wordline has been finely programmed, performs a read verify operation on one or more cells associated with the first wordline.

### TECHNICAL FIELD

Embodiments of the disclosure relate generally to memory sub-systems, and more specifically, relate to timing and cadence of a read verification operation with respect to programming operation in a memory device in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the present disclosure.

FIGS. 2A-2E illustrate example steps in a method for performing a read verification after performing a multi-pass programming operation in a memory device in a memory sub-system.

FIG. 3 is a flow diagram of an example method for performing a read verification after performing a multi-pass programming operation in a memory device in a memory sub-system.

FIG. 4 is a block diagram of an example computer system in which embodiments of the present disclosure can operate.

### DETAILED DESCRIPTION

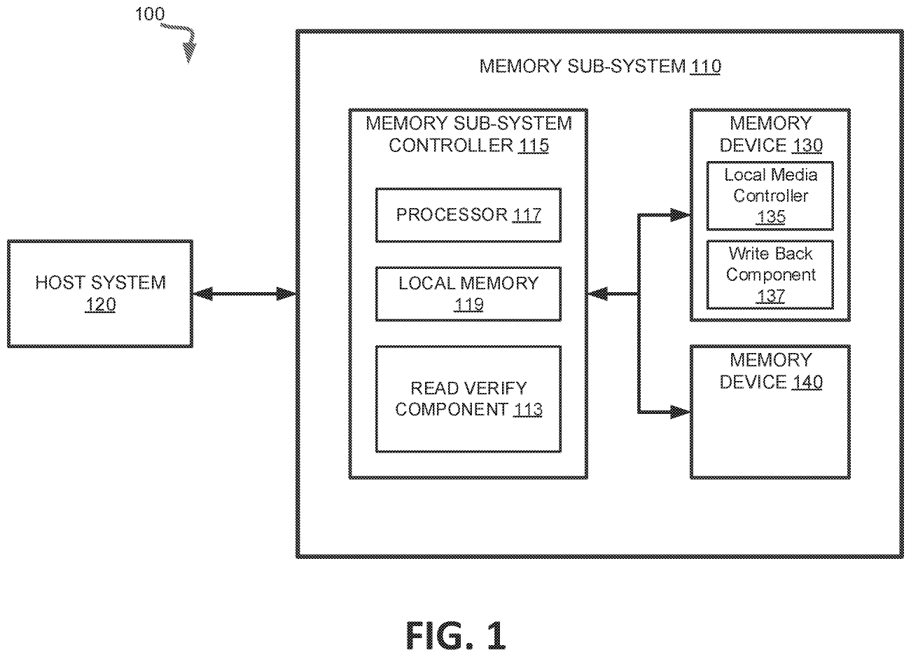

Aspects of the present disclosure are directed to systems and methods for performing a read verification after performing a multi-pass programming operation in a memory device in a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a three-dimensional cross-point (“3D cross-point”) memory device that is a cross-point array of non-volatile memory that can perform bit storage based on a change of bulk resistance, in conjunction with a stackable cross-gridded data access array. Another example of a non-volatile memory device is a negative-and (NAND) memory device. Other examples of non-volatile memory devices are described below in conjunction with FIG. 1. Each of the memory device can include one or more arrays of memory cells. A memory cell (“cell”) is an electronic circuit that stores information. Depending on the cell type, a cell can store one or more bits of binary information, and has various logic states that correlate to the number of bits being stored. The logic states can be represented by binary values, such as “0” and “1”, or combinations of such values. For example, a single level cell (SLC) can store one bit of information and has two logic states. Similarly, a multi-level cell (MLC) can store two bits per cell, a triple level cell (TLC) can store three bits per cell, a quad level cell (QLC) can store four bits per cell, and a penta level cell (PLC) can store five bits per cell. The memory sub-system includes a memory sub-system controller that can communicate with the memory devices to perform operations such as reading data, writing data, or erasing data at the memory devices and other such operations. A memory sub-system controller is described in greater below in conjunction with FIG. 1.

The host system can send access requests (e.g., write command, read command) to the memory sub-system, such as to store data on a memory device at the memory sub-system and to read data from the memory device on the memory sub-system. The data to be read or written, as specified by a host request, is hereinafter referred to as “host data.” A host request can include logical address information (e.g., logical block address (LBA), namespace) for the host data, which is the location the host system associates with the host data. The logical address information (e.g., LBA, namespace) can be part of metadata for the host data. The metadata and host data, together, is hereinafter referred to as “payload.” Metadata, host data, and parity data, which is used for error correction, can collectively form an error correction code (ECC) codeword. Metadata can also include data version (e.g., used to distinguish age of data written), valid bitmap (which LBAs or logical transfer units contain valid data), etc.

When performing memory access operations, such as read operations (e.g., in response to a received memory access request/command), certain memory sub-systems take action to correct any errors present in the data being read. For example, upon reading data from a memory device in response to a request, the memory sub-system controller can perform an error detection and correction operation. The error detection and correction operation includes identifying a number of errors (e.g., bit flip errors) in the read data. The memory sub-system can have the ability to correct a certain number of errors (e.g., using error correction code (ECC)). As long as the number of errors in the data are less than the ECC capability of the memory sub-system, the errors can be corrected before the data is provided to the requestor (e.g., the host system). In an attempt to prevent those same errors from being present when a subsequent memory access operation is performed on the same management unit (or super management unit), the memory sub-system can perform a write back operation. In a write back operation, the data from the management unit is overwritten with the corrected data that was just read from the memory device. Thus, any errors that were present in the data when it was read will be corrected so that those errors are not present going forward. However, certain memory sub-systems lack any feedback mechanism to ensure that no errors are introduced to the data during the write back operation. Furthermore, there is no way to determine the physical location on the storage media where the management unit is degraded and where additional errors in the stored data stored are likely to occur.

Negative-and (NAND) blocks include a set of pages which are organized into page stacks or groups of pages which are written together. The pages are numbered from 0 to N−1 with certain groups of pages paired together for programming, and the pages can be programmed in a particular order in order to guarantee data integrity. For example, if pages 0 and 1 form a page stack together, followed by pages 2 and 3, 4 and 5, and 6 and 7, each of these page stacks would be programmed in an increasing order. Some programming schemes may require multiple passes where a page stack is programmed on an initial pass and is left in an intermediary state, and later programmed again for a second or even a third pass until the page stack is fully programmed in its final, programmed state. Page stacks can also be grouped into sets which share the same NAND wordline. A programming operation of a NAND page stack may result in either a program pass or program failure status. However, a passing status from a programming operation does not necessarily guarantee data integrity and the programming operation may have actually resulted in what is referred to as a “silent program failure” where data integrity is compromised even though a passing programming status was received. Higher system level mechanisms are required to protect against these silent program failures and to avoid exposing too many data loss events to the host system, which is reading data from the memory sub-system (e.g., a solid-state drive (SSD)) comprising the NAND blocks. For better performance, a certain Uncorrectable Bit Error Rate (UBER) is required such that only some number of bits of data are uncorrectable by the SSD out of X bits read. For example, an UBER of 1e-14 requires that only 1 bit out of 1*10\hat{ }14 bits read was not error corrected by the memory sub-system. Therefore, a lower UBER results in better performance of the memory sub-system.

In traditional memory sub-systems, one method to avoid silent program failures involves striping parity bits across multiple NAND planes and/or dies such that if data is lost on one plane or die it can be reconstructed using the data from the rest of the planes or dies in a stripe. This method is commonly referred to as a redundant array of inexpensive disks (RAID) scheme. In Zoned Namespace (ZNS) SSDs, however, a parity or RAID scheme is not used within the SSD and the read verification process is left to higher level host software storage stacks. However, there is still an LIBER requirement for SSDs, which necessitates that actions be taken to avoid silent program failures.

One such method involves keeping two copies of the host data; one copy in the NAND (e.g., a SLC NAND) with higher quality and a guaranteed data integrity, and another copy as the final, intended destination for the data in bulk NAND storage (e.g., a QLC NAND) with lower intrinsic data integrity. The first copy is maintained until the second copy can be written and then be verified by reading it back, commonly referred to as “read verification.”

However, performing a read operation right after a program operation may result in a high bit error rate. Similarly, performing a read verify operation right after a program operation may result in a false “silent program failure.” Thus, there is a need to introduce a delay between a read operation and a program operation in order to let the NAND cells' Vt settle down. On the other hand, performing a read verify operation after an entire block is programmed means that the source data needs to be held in SLC cache for a longer period, e.g., the SLC cache can only be released after performing a read verify operation on all the pages in QLC. This means that more blocks need to be allocated as SLC cache, and the drive capacity as seen by the host is lesser than its actual capacity.

Aspects of the present disclosure perform read verification after performing a multi-pass programming operation in a memory device in a memory sub-system. In one embodiment, the memory sub-system controller performs a first pass of a multi-pass programming operation to coarsely program a first wordline. The memory sub-system controller then performs a second pass to coarsely program a second wordline adjacent to the first wordline. The memory sub-system controller then performs a third pass to finely program the first wordline, and then performs a fourth pass to coarsely program a third wordline adjacent to the second wordline. The memory sub-system controller then performs a fifth pass to finely program the second wordline, and responsive to determining that the second wordline has been finely programmed, the memory sub-system controller then performs a read verify operation on one or more memory cells associated with the first wordline.

Advantages of this approach include, but are not limited to introducing a delay between a program operation and a read-verify operation in a read verify scheduling scheme. Additionally, read verify operations can be interleaved with programming operations throughout the programming of a NAND block, which creates a more even workload of programs and reads over time, resulting in better QoS. Alternatively or in addition, read verifies can be interleaved with programming an entire block followed by read verification of an entire block. Additionally, read verify operations can be naturally triggered off of program operation completions or read verify operations completions. The methods disclosed herein result in fewer silent errors, which may improve read performance due to decreased entry into read error recovery.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a Zoned Namespace (ZNS) SSD, a flash drive, a universal serial bus (USB) flash drive, an embedded Multi-Media Controller (eMMC) drive, a Universal Flash Storage (UFS) drive, a secure digital (SD) and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad level cells (QLCs), and penta level cells (PLCs) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

In some embodiments, the memory device 130 includes a write back component 137, which may perform a write operation (e.g., a programming operation) on one or more memory cells of the memory device 130. During a write operation, a memory cell of the memory device 130 may be programmed to store a desired logic state. In some cases, a plurality of memory cells may be programmed during a single write operation. The local media controller 135 may identify a target memory cell on which to perform the write operation.

In some embodiments, the memory sub-system 110 includes a read verify component 113 that performs read verification after a hardware write back operation on memory device 130. In some embodiments, the memory sub-system controller 115 includes at least a portion of read verify component 113. For example, the memory sub-system controller 115 can include a processor 117 (e.g., a processing device) configured to execute instructions stored in local memory 119 for performing the operations described herein. In other embodiments, read verify component 113 is part of memory sub-system 110, but is separate from memory sub-system controller 115. In other embodiments, local media controller 135 includes at least a portion of read verify component 113 and is configured to perform read verification after performing a multi-pass programming operation in the memory device 130. In one embodiment, the memory sub-system controller 115 performs a first pass of a multi-pass programming operation to coarsely program a first wordline. The memory sub-system controller 115 then performs a second pass to coarsely program a second wordline adjacent to the first wordline. The memory sub-system controller 115 then performs a third pass to finely program the first wordline, and then performs a fourth pass to coarsely program a third wordline adjacent to the second wordline. The memory sub-system controller 115 then performs a fifth pass to finely program the second wordline, and responsive to determining that the second wordline has been finely programmed, the memory sub-system controller 115 using the read verify component 113 performs a read verify operation on one or more memory cells associated with the first wordline.

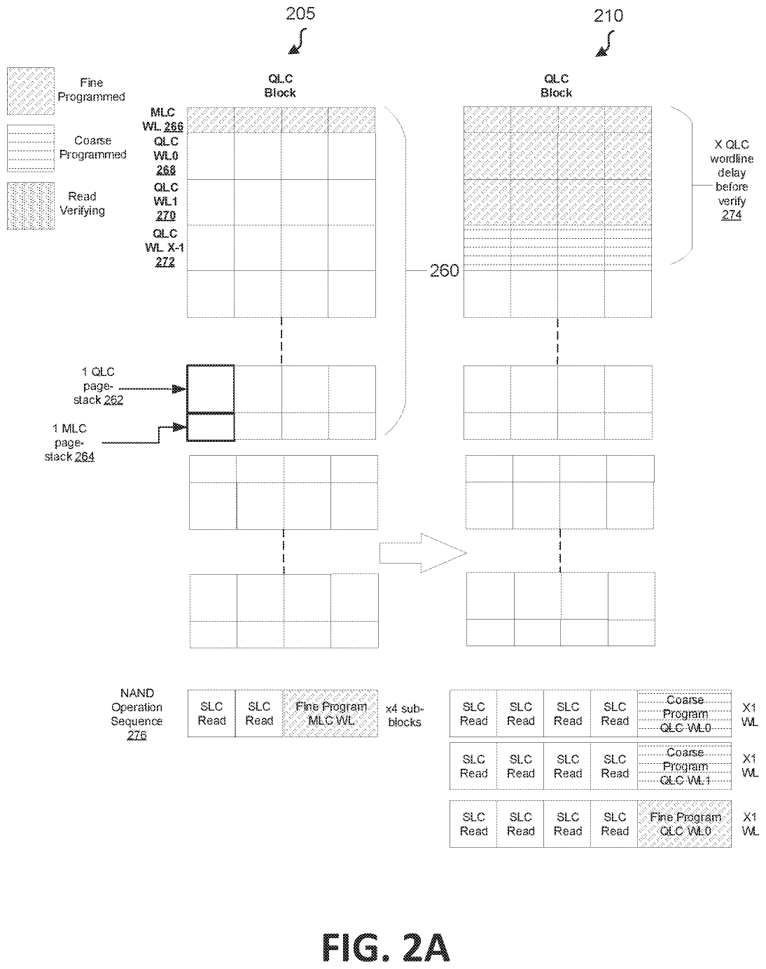

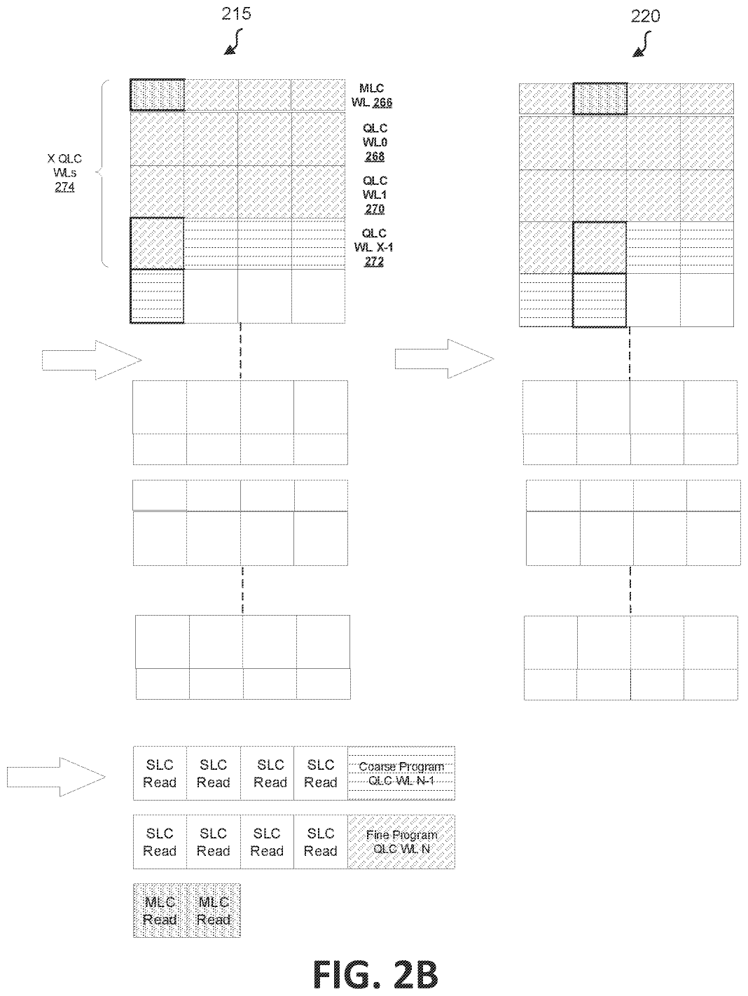

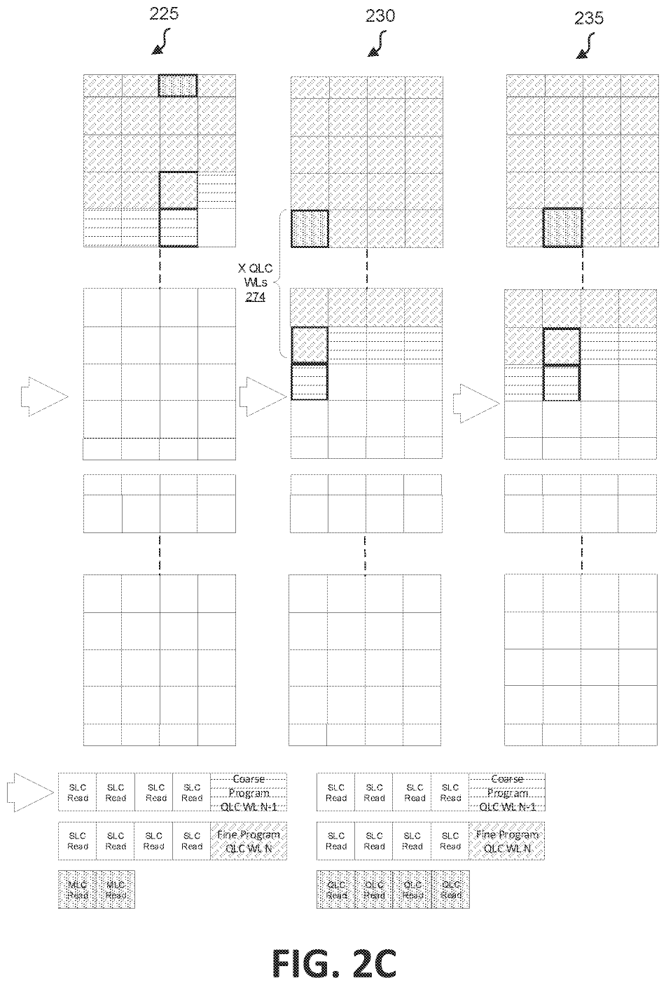

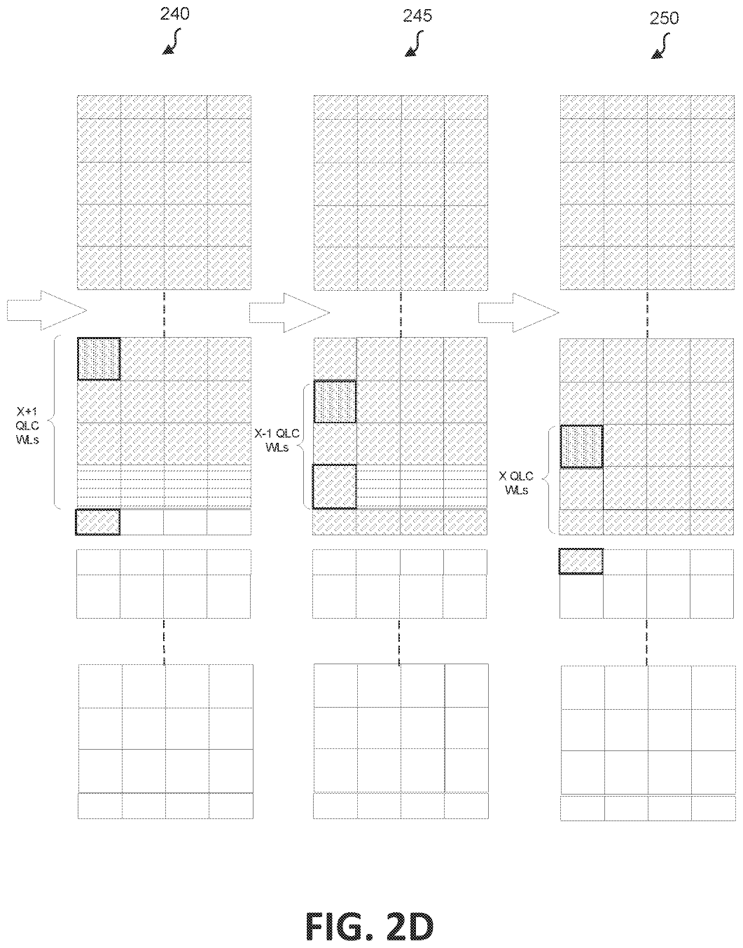

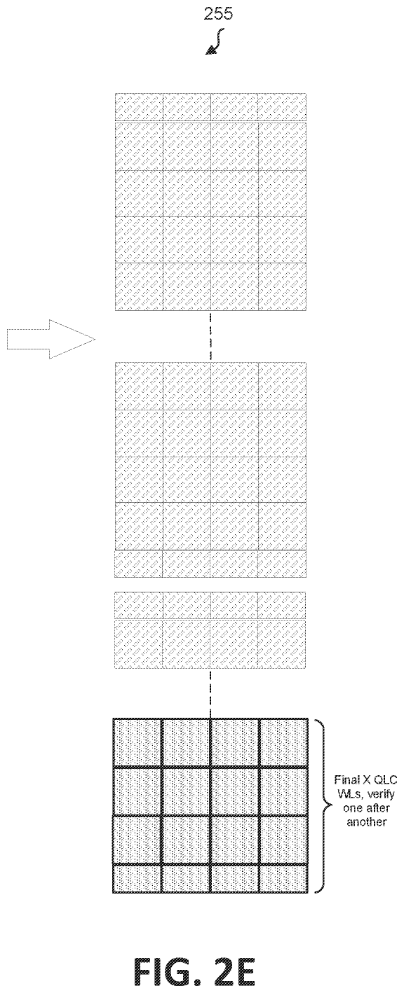

FIGS. 2A-E illustrate a flow diagram of an example method of performing a read verification after a multi-step program operation in a memory device in a memory sub-system in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by read verify component 113 and memory sub-system controller 115 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 2A, at operation 205, the processing logic of the memory controller performs fine programming of an MLC wordline 266 in a QLC block 265. MLC wordline 266 may include four sub-blocks, as an example. The QLC block 265 may include multiple QLC wordlines 268, 270, 262 and MLC wordlines 266, 264 on the edges of the QLC block 265. At the bottom of this figure is shown a NAND operation sequence 276 where the memory sub-system controller performs a first SLC read operation, followed by a second SLC read operation, then a fine programming of the MLC wordline 266, which includes four sub-blocks. Each cell is programmed in smaller steps with the fine programming pulses, which are substantially smaller than the coarse programming pulses in order to reduce the program disturb condition on the wordline. The fine programming pulses, in one embodiment, move the threshold voltages in multiple tenth volt or millivolt steps while the coarse programming pulses move the threshold voltages in a single step of a volt or greater. The fine programming pulses may be all the same voltage that has been determined to move the threshold voltage to the programmed state. The fine programming pulses can also be a plurality of different voltages as necessary to move the threshold voltage to the programmed state.

At operation 210, the processing logic of the memory sub-system controller performs coarse programming of QLC wordline 272 followed by fine programming of QLC wordlines 270, 268, and fine programming of MLC wordline 266. A coarse programming pulse is the initial programming step that requires the largest voltage on the wordline. Thus, the maximum program disturb is experienced on the first programming pulse since the effects on neighboring cells can be fixed with smaller, less disturbing programming pulses.

In one embodiment, the magnitude of the coarse programming pulse is set in response to the data to be programmed into the target memory cell as well as the data being programmed in neighboring memory cells. The programming pulse generation algorithm uses the desired state (i.e., threshold voltage) of the target memory cell to determine the programming voltage required to reach a certain percentage of that threshold voltage. This programming pulse is then used to bias the target memory cell. The threshold voltages of adjacent memory cells are then read to determine the effect of the coarse programming pulse. For example, a programming pulse might be 16V to move the target cell's threshold voltage from −3V to 0V. After this programming pulse, the adjacent memory cells are read to determine their current threshold voltages after the program disturb effects caused by the target cell coarse programming. The coarse programming of the adjacent memory cells takes into account the new threshold voltages by using the new threshold voltages as the starting point for the programming of the adjacent cells. The adjacent cells are then programmed with their own respective coarse programming voltage. Therefore, the coarse programming programs the cells along a wordline with large, high voltage steps to an initial threshold voltage. The fine programming programs the cells along the wordline with smaller high voltage steps to a final threshold voltage.

At operation 210, the memory sub-system controller introduces a delay between the time when a page-stack is programmed and when a read verify operation is performed to a finite settling time 274. The settling time 274 can range from the time it takes to coarsely program one additional QLC wordline to a maximum delay of the time it takes to program an entire QLC block 265. Referring now to FIG. 2B, at operation 215, the memory controller performs coarse programming of the first four wordlines, fine programming of the first three wordlines, and then initiates read verification of the first sub-block in the first wordline 266. The read verification operation is based on a bit line discharge verification process. First, a bit line is charged. Next, a verification pulse is provided to the control gate (or steering gate) of the memory cell attached to that bit line. The bit line is then allowed to discharge. Based on the rate of discharge, it can be determined whether the memory cell is above or below a particular threshold voltage level. Therefore, the read verification operation performs a bit line discharge analysis based on timing information, discharge voltage information, or a current value of the non-volatile storage elements.

At operation 220, the memory sub-system controller performs fine programming of the next cell in the fourth wordline and performs read verification of the same cell in the first wordline. As illustrated in this figure, the memory controller introduces a “delay” between the fine programming step and the read verification step. In some embodiments, the read verify granularity matches the programming granularity of one (1) page-stack. In some embodiment, the read verify granularity and the programming granularity can be an entire NAND block. In order to create a natural time delay between a page stack being programmed and later read verified, read verify can be delayed by some number X wordlines after programming, such that wordline N−X is read verified after wordline N is being programmed. The natural trigger for a read verify operation can be the program completion status of a programming operation on wordline N. This allows the memory controller to match the page-stack based programming granularity and also provides a straight-forward mechanism to interleave read verify operations with programming operations. However, for the final X wordlines in a NAND block, there are no wordlines N+X to be programmed which would trigger a read verify operation. Therefore, when the final page-stack in a block is programmed, the read verify operation for wordlines N−X would be triggered as normal, but the subsequent read verify operations for the final X wordlines would also be triggered one after another with each read verify operation triggered off of the completion of the previous read verify operation until every page/page-stack in the block has been read verified. The delay time for the last X wordlines, however, must meet the required read verify delay timing requirements, as discussed above. Generally the NAND read time Tᵣ is less than the NAND programming time T_{prog}. For read verification operations on wordlines, except for the final X wordlines, which are done in a burst once a block is fully programmed, the required delay time between programming and read verification can be >=the time it takes to program X wordlines. Assuming there are four sub-blocks in a wordline as shown in FIGS. 2A-2E, the timing of the read verify can be determined as shown in Equation (1).

T_{verify}=4X*T_{prog} (1)

However, at the end of the NAND block, the delay between programming the last sub-block and read verification of the last sub-block is only due to other read verification operations on the last X wordlines in the block. Thus the minimum read verification delay time can be determined as shown in Equation (2).

T_{verify}=4X*Tᵣ<4X*T_{prog} (2)

Therefore, the number of wordlines to delay verification can be tuned such that the minimum time delay between programming the final sub block and the verification of the final sub-block meets the required read verification delay time as shown in Equations (3) and (4).

T_{verify}=4X*Tᵣ≥4X*T_{required} (3)

X≥T_{required}/4Tᵣ (4)

Referring now to FIG. 2C, at operation 225, the delay between the programming operation and the read verification operation is three (X+1). However, at operation 230 and 235, the delay between the programming operation and the read verification operation is reduced to two (X). Similarly, as shown in FIG. 2D, at operation 240, the delay between the programming operation and the read verification operation is three (X+1). However, at operation 245, the delay between the programming operation and the read verification operation is reduced to one (X−1). At operation 250, the delay between the programming operation and the read verification operation is modified to two (X). Referring to FIG. 2E, at operation 255, for the final X wordlines in a NAND block, there are no wordlines N+X to be programmed which would trigger a read verify operation. Therefore, when the final page-stack in a block is programmed, the read verify operation for wordlines N−X would be triggered as normal, but the subsequent read verify operations for the final X wordlines would also be triggered one after another with each read verify operation triggered off of the completion of the previous read verify operation until every page/page-stack in the block has been read verified. The delay time for the last X wordlines, however, must meet the required read verify delay timing requirements, as discussed above.

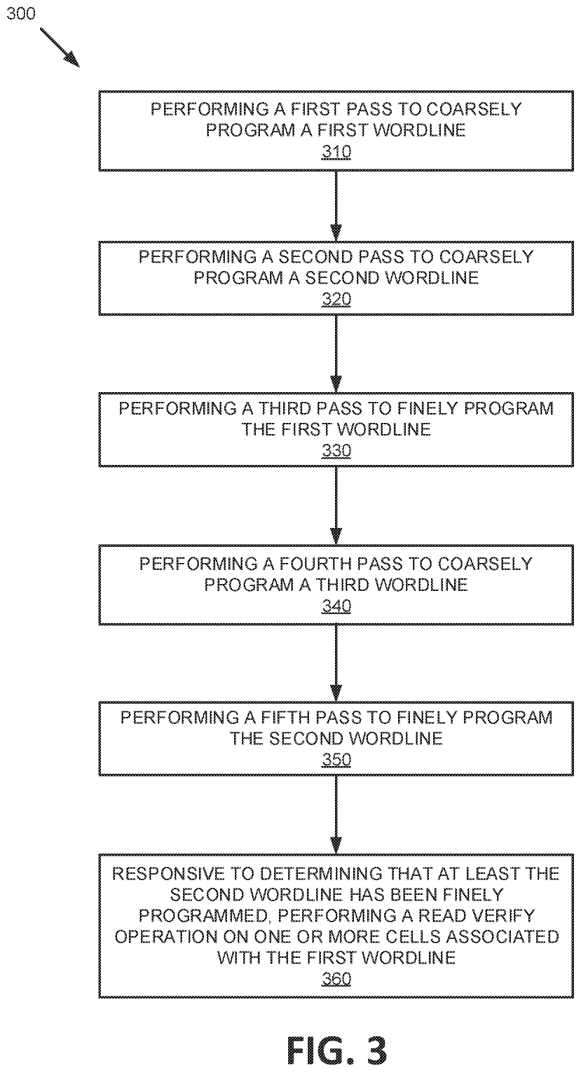

FIG. 3 is a flow diagram of an example method of performing a read verification operation after a multi-pass programming operation in a memory device in a memory sub-system. in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by read verify component 113, write back component 137, and local media controller 135 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 310, the processing logic of the memory sub-system controller performs a first pass of a multi-pass programming operation to coarsely program a first wordline (e.g., QLC wordline 270 in FIG. 2B). At operation 320, the processing logic of the memory sub-system controller performs a second pass to coarsely program a second wordline adjacent to the first wordline (e.g., QLC wordline 272 in FIG. 2B). At operation 330, the processing logic of the memory sub-system controller performs a third pass to finely program the first wordline (e.g., QLC wordline 270 in FIG. 2B), and then performs a fourth pass to coarsely program a third wordline adjacent to the second wordline (e.g., QLC wordline 268 in FIG. 2B). At operation 340, the processing logic of the memory sub-system controller performs a fifth pass to finely program the second wordline (e.g., QLC wordline 272 in FIG. 2B), and responsive to determining that the second wordline has been finely programmed, the memory sub-system controller then performs a read verify operation on one or more cells associated with the first wordline (e.g., QLC wordline 270 in FIG. 2B).

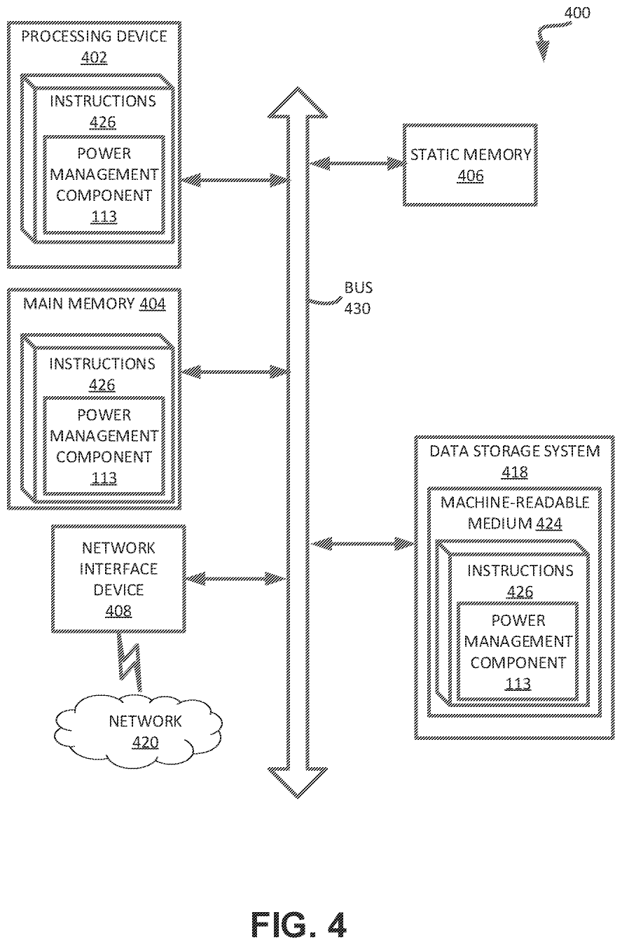

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to read verify component 113, memory sub-system controller 115, or local media controller 135 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to read verify component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method for programming memory cells in a memory device, the method comprising:
performing a first pass of a multi-pass programming operation to coarsely program a first wordline of the memory device;
performing a second pass of the multi-pass programming operation to coarsely program a second wordline of the memory device, wherein the second wordline is adjacent to the first wordline;
performing a third pass of the multi-pass programming operation to finely program the first wordline of the memory device;
performing a fourth pass of the multi-pass programming operation to coarsely program a third wordline of the memory device, wherein the third wordline is adjacent to the second wordline;
performing a fifth pass of the multi-pass programming operation to finely program the second wordline of the memory device; and
responsive to determining that at least the second wordline has been finely programmed, performing a read verify operation on one or more memory cells associated with the first wordline.

2. The method of claim 1, wherein performing the first pass of the multi-pass programming operation comprises:
programming memory cells associated with the first wordline to an initial threshold voltage by causing a first sequence of programming voltages to be applied to the first wordline, wherein each successive voltage in the first sequence is incremented by a first voltage step.

3. The method of claim 2, wherein performing the third pass of the multi-pass programming operation comprises:
programming the memory cells associated with the first wordline to a final threshold voltage by causing a second sequence of programming voltages to be applied to the first wordline, wherein each successive voltage in the second sequence is incremented by a second voltage step that is less than the first voltage step.

4. The method of claim 1, wherein the read verification operation is based on a bit line discharge process based on timing information, based on discharge voltage information, or based on a current value of the one or more memory cells.

5. The method of claim 1, wherein a granularity with which the coarse programming, fine programming, and read verify operations are performed comprises a block, a word line, a page, or a stack of pages.

6. The method of claim 1, wherein the memory cells associated with the first wordline are configured to be a multi-level cells (MLC) capable of storing two bits per cell.

7. The method of claim 1, wherein the memory cells associated with the second and third wordlines are configured to be a quad-level cell (QLC) capable of storing four bits per cell.

8. The method of claim 1, further comprising:
storing a first copy of host data in one or more memory cells associated with a first block;
storing a second copy of the host data in one or more memory cells associated with a second block, wherein the second block has greater bits per cell than the first block; and
responsive to read verifying the second copy of the host data in one or more memory cells associated with the second block, deleting the first copy of the host data in the one or more memory cells associated with the first block.

9. The method of claim 8, wherein the second copy has lower intrinsic data integrity than the first copy of the host data.

10. A system comprising:
a memory device; and
a processing device, operatively coupled with the memory device, to perform operations comprising:
performing a first pass of a multi-pass programming operation to coarsely program a first wordline of the memory device;
performing a second pass of the multi-pass programming operation to coarsely program a second wordline of the memory device, wherein the second wordline is adjacent to the first wordline;
performing a third pass of the multi-pass programming operation to finely program the first wordline of the memory device;
performing a fourth pass of the multi-pass programming operation to coarsely program a third wordline of the memory device, wherein the third wordline is adjacent to the second wordline;
performing a fifth pass of the multi-pass programming operation to finely program the second wordline of the memory device; and
responsive to determining that at least the second wordline has been finely programmed, performing a read verify operation on one or more memory cells associated with the first wordline.

11. The system of claim 10, wherein performing the first pass of the multi-pass programming operation comprises:
programming memory cells associated with the first wordline to an initial threshold voltage by causing a first sequence of programming voltages to be applied to the first wordline, wherein each successive voltage in the first sequence is incremented by a first voltage step.

12. The system of claim 10, wherein performing the third pass of the multi-pass programming operation comprises:
programming the memory cells associated with the first wordline to a final threshold voltage by causing a second sequence of programming voltages to be applied to the first wordline, wherein each successive voltage in the second sequence is incremented by a second voltage step that is less than the first voltage step.

13. The system of claim 10, wherein the read verification operation is based on a bit line discharge process based on timing information, based on discharge voltage information, or based on a current value of the one or more memory cells.

14. The system of claim 10, wherein a granularity with which the coarse programming, fine programming, and read verify operations are performed comprises a block, a word line, a page, or a stack of pages.

15. The system of claim 10, wherein the memory cells associated with the first wordline are configured to be a multi-level cells (MLC) capable of storing two bits per cell, and the memory cells associated with the second and third wordlines are configured to be a quad-level cell (QLC) capable of storing four bits per cell.

16. A non-transitory computer-readable storage medium comprising instructions that, when executed by a processing device, cause the processing device to perform operations comprising:
performing a first pass of a multi-pass programming operation to coarsely program a first wordline of a memory device;
performing a second pass of the multi-pass programming operation to coarsely program a second wordline of the memory device, wherein the second wordline is adjacent to the first wordline;
performing a third pass of the multi-pass programming operation to finely program the first wordline of the memory device; and
causing a delay before performing a read verify operation on one or more memory cells associated with the first wordline.

17. The non-transitory computer-readable storage medium of claim 16, wherein causing the delay further comprises:
performing a fourth pass of the multi-pass programming operation to coarsely program a third wordline of the memory device, wherein the third wordline is adjacent to the second wordline;
performing a fifth pass of the multi-pass programming operation to finely program the second wordline of the memory device; and
determining that at least the second wordline has been finely programmed.

18. The non-transitory computer-readable storage medium of claim 16, wherein performing the first pass of the multi-pass programming operation further comprises:
programming memory cells associated with the first wordline to an initial threshold voltage by causing a first sequence of programming voltages to be applied to the first wordline, wherein each successive voltage in the first sequence is incremented by a first voltage step.

19. The non-transitory computer-readable storage medium of claim 16, wherein performing the third pass of the multi-pass programming operation comprises:
programming the memory cells associated with the first wordline to a final threshold voltage by causing a second sequence of programming voltages to be applied to the first wordline, wherein each successive voltage in the second sequence is incremented by a second voltage step that is less than the first voltage step.

20. The non-transitory computer-readable storage medium of claim 16, wherein the read verification operation is based on a bit line discharge process based on timing information, based on discharge voltage information, or based on a current value of the one or more memory cells.
